(19) United States
(12) Patent Application Publication
(10) Pub. No.: US 2007/0001246 A1
(43) Pub. Date: Jan. 4, 2007

(54) Gate electrode with double diffusion barrier and fabrication method of semiconductor device including the same

(75) Inventors: Kwan-Yong Lim, Ichon-shi (KR); Min-Gyu Sung, Ichon-shi (KR); Heung-Jae Cho, Ichon-shi (KR); Hong-Seon Yang, Ichon-shi (KR); Seung-Ryong Lee, Ichon-shi (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: HYNIX SEMICONDUCTOR, INC.

(21) Appl. No.: 11/262,944

(22) Filed: Nov. 1, 2005

(30) Foreign Application Priority Data
Jun. 30, 2005 (KR) 2005-0058145

(51) Int. Cl. H01L 29/94; H01L 21/3205

(52) U.S. Cl. 257/412; 257/413; 438/585; 257/E29.126

(57) ABSTRACT

A gate electrode with a double diffusion barrier and a fabrication method of a semiconductor device including the same are provided. The gate electrode of a semiconductor device includes: a silicon electrode; a double diffusion barrier formed on the silicon electrode and including at least a crystalline tungsten nitride-based layer; and a metal electrode formed on the double diffusion barrier.

### FIELD OF THE INVENTION

The present invention relates to a semiconductor device and a method for fabricating the same; and, more particularly, to a gate electrode in a semiconductor device with a double diffusion barrier and a method for fabricating a semiconductor device including the same.

### DESCRIPTION OF RELATED ARTS

Recently, to reduce resistance of a gate electrode in a formation process of a semiconductor device, a polycide gate electrode with a tungsten silicide (WSiₓ)/polysilicon structure and a tungsten poly-metal gate electrode with a tungsten (W)/tungsten nitride-based layer (WNₓ)/polysilicon structure, which further reduces resistance, are used. The tungsten nitride layer, which is used as a diffusion barrier in the tungsten poly-metal gate electrode, is in an amorphous state. The amorphous tungsten nitride layer is expressed as ‘a-WNₓ’, where x representing an atomic ratio of nitrogen ranges from 0.1 to 1.0.

FIG. 1 is a cross-sectional view illustrating a conventional semiconductor device with a tungsten poly-metal gate, and the semiconductor device includes a gate electrode with a W/WNₓ/polysilicon structure.

As shown in FIG. 1, a gate oxide layer 12 is formed on a semiconductor substrate 11, and a gate electrode 100 is formed on the gate oxide layer 12. Herein, the gate electrode 100 has a W/WNₓ/polysilicon structure, wherein a polysilicon layer 13, a tungsten nitride layer 14 and a tungsten layer 15 are sequentially formed. Then, a gate hard mask 16 is formed on the gate electrode 100.

Subsequently, oxide layers 17 are formed on the lateral walls of the polysilicon layer 13 and gate bird's beaks 18 are formed at the edges of the gate electrode 100 through a selective gate re-oxidation process.

The gate electrode 100 with the W/WNₓ/polysilicon structure illustrated in FIG. 1 has an advantage of having only one sixth of the resistance of a WSiₓ/polysilicon structure. However, there is a disadvantage. Because the tungsten nitride layer 14 is in an amorphous state, nitrogen included in the nitride layer 14 is decomposed during a follow-up high temperature heat process or a selective gate re-oxidation process, resulting in a formation of an insulation layer such as silicon nitride (SiNₓ) and silicon oxynitride (SiOₓN_{y}) in an uneven thickness ranging from 2 nm to 3 nm on an interface between the tungsten layer 15 and the polysilicon layer 13.

Such insulation layer affects device operation characteristics such as a resistance capacitance (RC) delay. Especially, such insulation layer induces faulty operations during a high-speed operation at high-frequency.

Thus, recently, attempts of inserting layers such as Wsiₓ, W and titanium (Ti) between the amorphous tungsten nitride layer and the polysilicon layer have been made to complement the tungsten nitride layer in the amorphous state, which can be easily decomposed during a follow-up high temperature heat process. That is, double diffusion barriers such as a-WNₓ/WSiₓ, a-WNₓ/W and a-WNₓ/Ti have been suggested.

However, even when using the above-described double diffusion barrier, there arise limitations as shown in FIGS. 2A to 2C.

FIGS. 2A to 2C are cross-sectional transmission electron microscope (TEM) views illustrating a conventional gate electrode with a double diffusion barrier, obtained after a heat process using N₂ gas at a temperature of 850° C. for 120 seconds. The conventional gate electrode has a W/WNₓ/polysilicon structure.

As shown in FIG. 2A, even in the case of an a-WNₓ/WSiₓ double diffusion barrier, there exists a disadvantage of S—-N being formed on an interface between the tungsten layer and the polysilicon layer due to the reaction between silicon existing in WSi_{X} and nitrogen decomposed from a-WNₓ.

Furthermore, as shown in FIG. 2B, in the case of an a-WNₓ/W double diffusion barrier, the a-WNₓ/W double diffusion barrier has extremely vulnerable heat stability, resulting in an abnormal silicide reaction between the tungsten layer and the polysilicon layer during the aforementioned heat process.

Moreover, as shown in FIG. 2C, in the case of an a-WNₓ/Ti double diffusion barrier, heat stability of titanium nitride (TiN) is relatively superior. Herein, TiN is formed by nitrification of the top surface of a Ti layer during an a-WNₓ layer formation. Thus, an insulation layer does not form on the interface between the tungsten layer and the polysilicon layer, and the abnormal silicide reaction does not occur. However, there is a difficulty in the process, for the diffusion barrier including Ti must be blocked with a layer such as a Si—N layer before a re-oxidation process because of an abnormal oxidation of TiN or Ti during a follow-up selective gate re-oxidation process.

Generally, the gate re-oxidation process in a semiconductor device fabrication process is performed to: recover micro-trenches and damages caused by a plasma after an etching process, wherein the micro-trenches and the plasma damages are accrued during the etching process on a gate oxide layer; oxidize residual electrode materials on a silicon substrate; and form gate bird's beaks by increasing the thickness of portions of the gate oxide layer at the edges of the gate structure. As a result of these effects, reliability of the semiconductor device can be improved. Especially, the thickness and quality of the portions of the gate oxide layer at the edges of the gate structure have great effects over a hot carrier characteristic, a sub-threshold characteristic, a punch-through characteristic, device operation speed, and reliability. Therefore, the gate re-oxidation process for forming the gate bird's beaks at the edges of the gate structure is essential.

In the case of a W/WNₓ/polysilicon structure, there is a disadvantage of tungsten becoming rapidly expanded in volume during oxidation in a gate re-oxidation process in an atmosphere of O₂ or H₂O. Therefore, in the case of the W/WNₓ/polysilicon structure, a gate re-oxidation process using a fraction of O₂ or H₂O in an H₂ atmosphere for the heat process to oxidize the polysilicon layer and the silicon substrate, but not the W/WNₓ layer, is recommended for use. Such process is commonly referred to as a selective gate re-oxidation process, and generally, W and molybdenum (Mo) are the only known metals whereon the selective gate re-oxidation process at a temperature under 1,100° C. can be applied to. Thus, the fact that a tungsten layer is formed on a polysilicon layer in most cases of poly-metal gates may reflect that there are limitations in kinds of the metal to be formed on the polysilicon layer.

### SUMMARY OF THE INVENTION

It is, therefore, an object of the present invention to provide a gate electrode of a semiconductor device and a method for fabricating the same provided with a double diffusion barrier capable of inhibiting an insulation layer formation on an interface between a polysilicon layer and a tungsten layer during a tungsten poly-metal gate process for forming the polysilicon layer and the tungsten layer, as well as maintaining superior heat stability in a high-temperature heat process.

In accordance with an aspect of the present invention, there is provided a gate electrode of a semiconductor device, including: a silicon electrode; a double diffusion barrier formed on the silicon electrode and including at least a crystalline tungsten nitride-based layer; and a metal electrode formed on the double diffusion barrier.

In accordance with another aspect of the present invention, there is provided a method for fabricating a semiconductor device, including: forming a gate insulation layer on a semiconductor substrate; forming a silicon electrode on the gate insulation layer; forming a double diffusion barrier including at least a crystalline tungsten nitride-based layer on the silicon electrode; forming a metal electrode on the double diffusion barrier; forming a gate hard mask on the metal electrode; performing a gate patterning process to form a gate line, wherein the gate line includes the silicon electrode, the double diffusion barrier, the metal electrode and the gate hard mask formed in sequential order; and performing a selective gate re-oxidation process to form gate bird's beaks at the lower edges of the gate line.

### BRIEF DESCRIPTION OF THE DRAWINGS

The above and other objects and features of the present invention will become better understood with respect to the following description of the specific embodiments given in conjunction with the accompanying drawings, in which:

FIG. 1 is a cross-sectional view illustrating a semiconductor device with a conventional tungsten poly-metal gate;

FIGS. 2A to 2C are cross-sectional TEM views illustrating a gate electrode after a heat process using N₂ gas at a temperature of 850° C. for 120 seconds; wherein the gate electrode includes a conventional double diffusion barrier;

FIG. 3 is a cross-sectional view illustrating a poly-metal gate electrode structure in accordance with a specific embodiment of the present invention;

FIG. 4 is a graph illustrating x-ray diffractometer (XRD) spectra of an amorphous tungsten nitride (a-WNₓ) layer and a crystalline tungsten nitride (c-WNₓ) layer;

FIG. 5 is a graph illustrating x-ray photoelectron spectroscope (XPS) depth profiles of an amorphous tungsten nitride (a-WNₓ) layer and a crystalline tungsten nitride (c-WNₓ) layer;

FIG. 6 is a cross-sectional TEM view illustrating a W/c-WNₓ/W/polysilicon gate electrode structure after a heat process using N₂ gas at a temperature of 850° C. for 120 seconds in accordance with the specific embodiment of the present invention;

FIG. 7 is a time dependent dielectric breakdown (TDDB) graph illustrating a metal oxide semiconductor (MOS) capacitor structure with a W/a-WNₓ/W/polysilicon gate electrode and another MOS capacitor structure with a W/c-WNₓW/polysilicon gate electrode after full thermal processes using N₂ gas at approximately 988° C. for approximately 20 seconds and N₂ gas at approximately 850° C. for approximately 20 minutes; and

FIGS. 8A and 8B are cross-sectional views illustrating a method for fabricating a semiconductor device including a tungsten poly-metal gate electrode in accordance with the specific embodiment of the present invention.

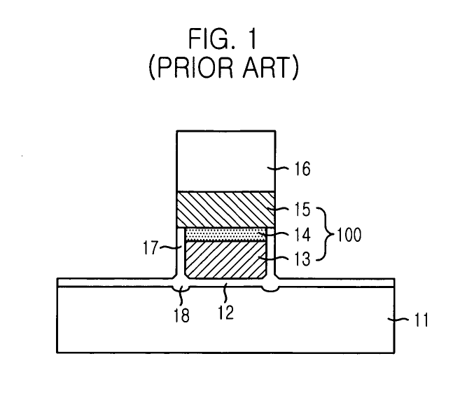

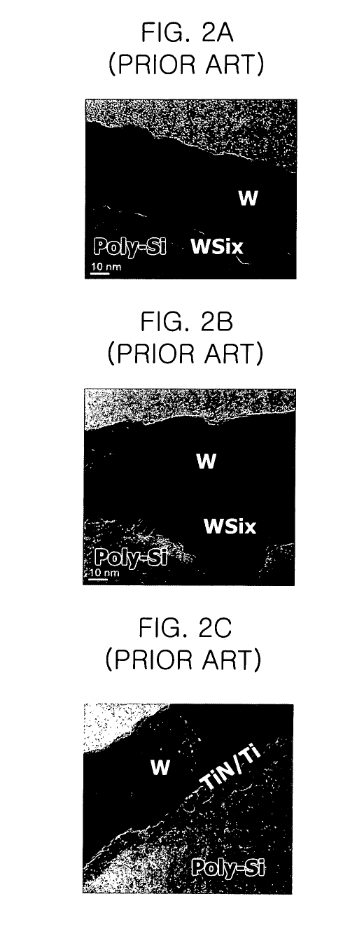

### DETAILED DESCRIPTION OF THE INVENTION

A gate electrode with a double diffusion barrier and a fabrication method of a semiconductor device including the same in accordance with exemplary embodiments of the present invention will be described in detail with reference to the accompanying drawings.

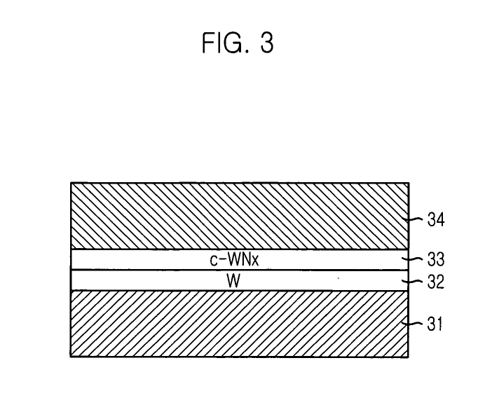

FIG. 3 is a cross-sectional view illustrating a poly-metal gate electrode structure in accordance with a specific embodiment of the present invention.

As shown in FIG. 3, the poly-metal gate electrode includes: a silicon electrode 31; a first diffusion barrier 32 formed on the silicon electrode 31; a second diffusion barrier 33 formed on the first diffusion barrier 32; and a metal electrode 34 formed on the second diffusion barrier 33. That is, the diffusion barrier of the poly-metal gate electrode has a double diffusion barrier structure including the first diffusion barrier 32 and the second diffusion barrier 33.

Firstly, the silicon electrode 31 is formed by employing one of polysilicon, polysilicon germanium (poly-Si₁₋ₓGeₓ), where x representing an atomic ratio of Ge ranges from approximately 0.01 to approximately 1.0, and metal silicide. Herein, the metal silicide includes one of nickel (Ni), chromium (Cr), cobalt (Co), titanium (Ti), tungsten (W), tantalum (Ta) and hafnium (Hf).

Furthermore, the first diffusion barrier 32 is a thin tungsten layer formed in a thickness ranging from approximately 10 Å to approximately 60 Å, and the second diffusion barrier 33 is a crystalline tungsten nitride layer (c-WNₓ), where x representing an atomic ratio of N is in a range of approximately 0.5 to 2.0. The c-WNₓ layer is formed in a thickness ranging from approximately 30 Å to approximately 100 Å. Also, the tungsten nitride layer used as the second diffusion barrier 33 contains more than approximately 40% of nitrogen within the layer. Herein, the percentage of nitrogen refers to a percentage before a heat process is performed. Meanwhile, the c-WNₓ layer used as the second diffusion barrier 33 may be polycrystalline having regional crystalloids.

Furthermore, the metal electrode 34 is formed by employing a tungsten layer.

According to the above description, the poly-metal gate electrode in accordance with the specific embodiment of the present invention can be structured as W/c-WNₓ/W/polysilicon.

By employing the c-WNₓ layer as the second diffusion barrier 33 and employing the W/c-WNₓ/W/polysilicon structure as the gate electrode, it is possible to fabricate a tungsten poly-metal gate electrode with extremely low interfacial contact resistance between tungsten and polysilicon and parasitic capacitance when compared with the conventional tungsten poly-metal gate electrode. Herein, the c-WNₓ layer contains more than approximately 40% of nitrogen (before a heat process) and does not easily become decomposed at a high temperature. Also, a thin layer of tungsten as the first diffusion barrier 32 is additionally inserted into the W/c-WNₓ/W/polysilicon structure to prevent surface nitrification of the silicon electrode 31, which includes silicon such as the lower polysilicon of the above gate electrode structure.

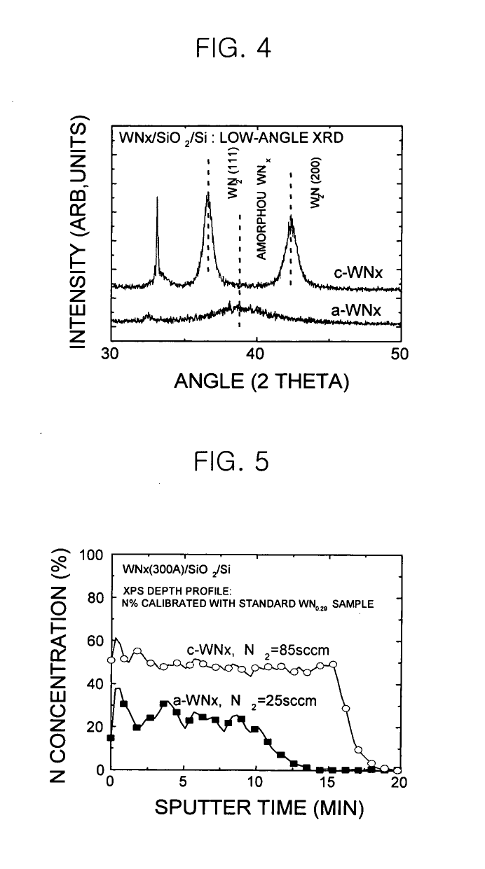

FIG. 4 is a graph illustrating x-ray diffractometer (XRD) spectra of an a-WNₓ layer and a c-WNₓ layer. As shown in FIG. 4, crystalloids of WNₓ and W₂N are not observed in the a-WNₓ layer. However, XRD peaks corresponding to crystalloids of W₂N whose lattice orientation is at 111 and W₂N whose lattice orientation is at 200 are observed in the c-WNₓ layer.

FIG. 5 is a graph illustrating x-ray photoelectron spectroscope (XPS) depth profiles of an a-WNₓ layer and a c-WNₓ layer. As shown in FIG. 5, nitrogen content of the a-WNₓ layer is less than 40%, whereas nitrogen content of the c-WNₓ layer is more than 40%.

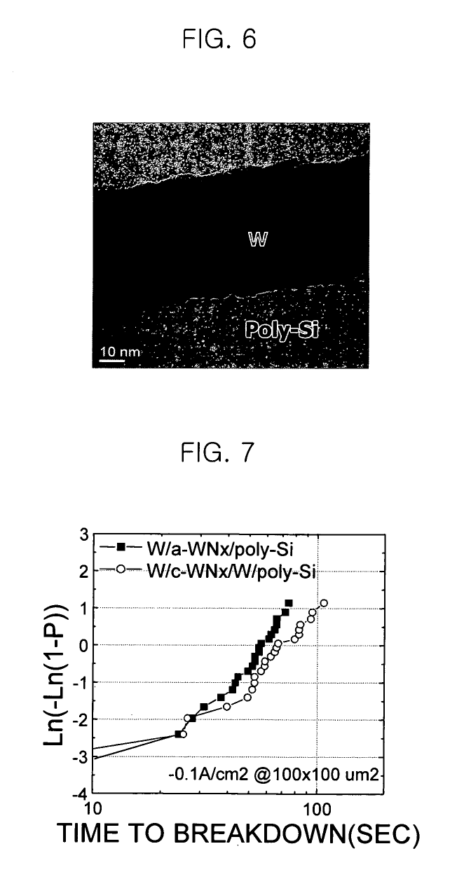

FIG. 6 is a cross-sectional TEM view illustrating a W/c-WNₓ/W/polysilicon gate structure after a heat process using N₂ gas at approximately 850° C. for approximately 120 seconds in accordance with the specific embodiment of the present invention. As shown in FIG. 6, there occurs no abnormal silicide reaction between the tungsten layer and the polysilicon layer.

FIG. 7 is a time dependent dielectric breakdown (TDDB) graph illustrating a metal oxide semiconductor (MOS) capacitor structure with a W/a-WNₓ/W/polysilicon gate electrode and another MOS capacitor structure with a W/c-WNₓ/W/polysilicon gate electrode, wherein both of the gate electrodes are obtained after full thermal processes using N₂ gas at approximately 988° C. for approximately 20 seconds and N₂ gas at approximately 850° C. for approximately 20 minutes. As shown in FIG. 7, a time-to-breakdown characteristic of the W/c-WNₓ/W/polysilicon gate electrode is relatively superior to the W/a-WNₓ/polysilicon gate electrode.

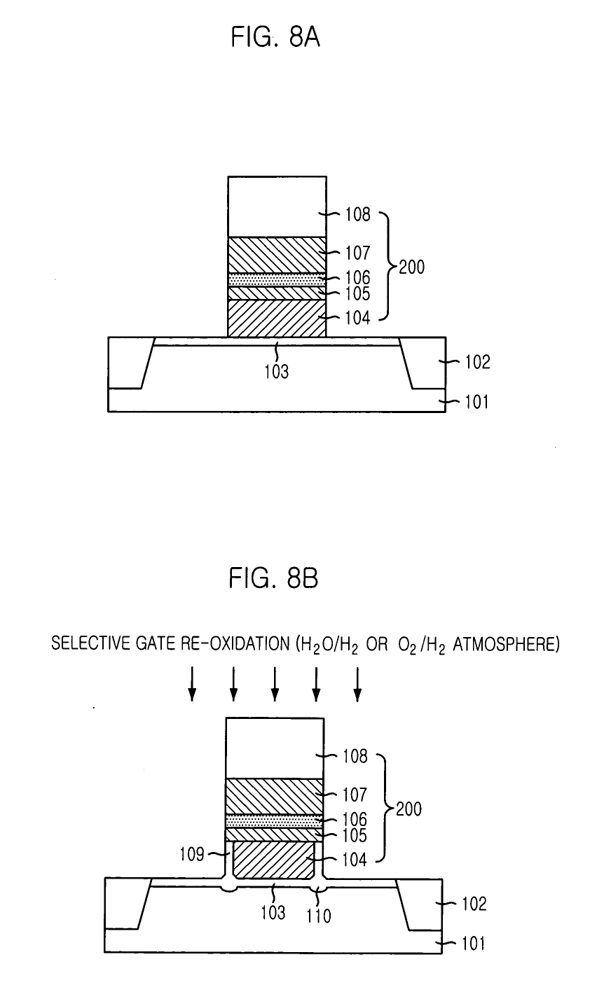

FIGS. 8A and 8B are cross-sectional views illustrating a method for fabricating a semiconductor device including a tungsten poly-metal gate electrode in accordance with the specific embodiment of the present invention.

As shown in FIG. 8A, device isolation regions 102 are formed in a semiconductor substrate 101 to isolate devices, and then various well and channel ion implantation processes are performed on the substrate 101.

Subsequently, a gate insulation layer 103 is formed on the substrate 101, and a polysilicon layer 104, a first tungsten layer 105, a tungsten nitride layer 106, a second tungsten layer 107, and a gate hard mask 108 are sequentially formed on the gate insulation layer 103.

Herein, the polysilicon layer 104 under the first tungsten layer 105 constitutes a silicon electrode. Besides polysilicon, the silicon electrode is formed by employing one of polysilicon germanium (poly-Si₁₋ₓGeₓ), where x representing an atomic ratio of Ge ranges from approximately 0.01 to approximately 1.0, and metal silicide. Herein, metal silicide includes one of Ni, Cr, Co, Ti, W, Ta and Hf.

Furthermore, the first tungsten layer 105 is formed in a thickness ranging from approximately 10 Å to approximately 60 Å, and the tungsten nitride layer 106 is a crystalline tungsten nitride layer (c-WNₓ), where x representing an atomic ratio of N ranges from approximately 0.5 to approximately 2.0, and is formed in a thickness ranging from approximately 30 Å to approximately 100 Å. Also, the tungsten nitride layer 106 contains more than 40% of nitrogen within the layer. Herein, the percentage of nitrogen refers to a percentage before a heat process is performed. Meanwhile, the c-WNₓ layer 106 may be polycrystalline having regional crystalloids.

Moreover, using a gate mask, a gate patterning process is performed to form a gate line 200 including the polysilicon layer 104, the first tungsten layer 105, the c-WNₓ layer 106, the second tungsten layer 107, and the gate hard mask 108.

As shown in FIG. 8B, a selective gate re-oxidation process is performed. During the selective gate re-oxidation process, the first tungsten layer 105, the c-WNₓ 106 and the second tungsten layer 107 are not oxidized, but the exposed lateral sides of the polysilicon layer 104 become selectively oxidized. As a result, oxide layers 109 are formed on both lateral walls of the polysilicon layer 104. Also, bird's beaks 110 of the gate insulation layer 103 are formed at the lower edges of the gate line 200. The above selective gate re-oxidation process is performed in an gaseous atmosphere of either H₂O/H₂ or O₂/H₂ at a temperature ranging from approximately 400° C. to approximately 850° C. The selective gate re-oxidation process is performed by employing one of an annealing method and a plasma method.

As another embodiment, a silicide thin film formed in a thickness ranging from approximately 30 Å to approximately 100 Å may be additionally inserted between the polysilicon layer and the W/c-WNₓ/W structure in the tungsten poly-metal gate electrode. Herein, the silicide thin film is formed by employing one of WSiₓ, TiSiₓ, TaSiₓ, MoSiₓ and HfSiₓ, wherein x representing an atomic ratio of Si ranges from approximately 1.0 to approximately 5.0. Inserting the silicide thin film as described above improves a diffusion barrier characteristic.

In accordance with the specific embodiment of the present invention, the double diffusion barrier with the crystalline tungsten nitride layer and the tungsten layer is inserted between the silicon electrode and the metal electrode to inhibit the interfacial insulation layer (e.g., Si—N) formation on the interface between the silicon electrode and the metal electrode, as well as to maintain superior heat stability which does not change even in a high-temperature heat process for a long period of time. As a result, the tungsten poly-metal gate electrode capable of high-speed operations can be realized.

The present application contains subject matter related to the Korean patent application No. KR 2005-58145, filed in the Korean Patent Office on Jun. 30, 2005, the entire contents of which being incorporated herein by reference.

While the present invention has been described with respect to certain specific embodiments, it will be apparent to those skilled in the art that various changes and modifications may be made without departing from the spirit and scope of the invention as defined in the following claims.

What is claimed is:

1. A gate electrode of a semiconductor device, comprising:
a silicon electrode;
a double diffusion barrier formed on the silicon electrode and including at least a crystalline tungsten nitride-based layer; and
a metal electrode formed on the double diffusion barrier.

2. The gate electrode of claim 1, wherein the double diffusion barrier includes a tungsten layer and the crystalline tungsten nitride-based layer formed in sequential order.

3. The gate electrode of claim 2, wherein the tungsten nitride-based layer includes nitrogen content of at least more than approximately 40%.

4. The gate electrode of claim 2, wherein the tungsten nitride-based layer is a polycrystalline thin film with regional crystalloids.

5. The gate electrode of claim 1, wherein the crystalline tungsten nitride-based layer is formed in a thickness ranging from approximately 30 Å to approximately 100 Å.

6. The gate electrode of claim 2, wherein the tungsten layer of the double diffusion barrier is formed in a thickness ranging from approximately 10 Å to approximately 60 Å.

7. The gate electrode of claim 1, wherein the metal electrode includes a tungsten layer.

8. The gate electrode of claim 1, wherein the silicon electrode includes one of polysilicon, polysilicon germanium (poly-Si₁₋ₓGeₓ), where x representing an atomic ratio of Ge ranges from approximately 0.01 to approximately 1.0, and metal silicide selected from a group consisting of nickel (Ni), chromium (Cr), cobalt (Co), titanium (Ti), tungsten (W), tantalum (Ta), and hafnium (Hf).

9. The gate electrode of claim 1, wherein a silicide thin film is additionally inserted between the double diffusion barrier and the silicon electrode.

10. The gate electrode of claim 9, wherein the silicide thin film is selected from a group consisting of WSiₓ, TiSiₓ, TaSiₓ, MoSiₓ and HfSiₓ, and the constant x representing an atomic ratio of Si ranges from approximately 1.0 to approximately 5.0.

11. A method for fabricating a semiconductor device, comprising:
forming a gate insulation layer on a semiconductor substrate;
forming a silicon electrode on the gate insulation layer;
forming a double diffusion barrier including at least a crystalline tungsten nitride-based layer on the silicon electrode;
forming a metal electrode on the double diffusion barrier;
forming a gate hard mask on the metal electrode;
performing a gate patterning process to form a gate line, wherein the gate line includes the silicon electrode, the double diffusion barrier, the metal electrode and the gate hard mask formed in sequential order; and
performing a selective gate re-oxidation process to form gate bird's beaks at the lower edges of the gate line.

12. The method of claim 11, wherein the forming of the double diffusion barrier includes:
forming a first diffusion barrier, which is formed by employing a tungsten layer, on the silicon electrode; and
forming a second diffusion barrier, which is formed by employing the crystalline tungsten nitride-based layer, on the first diffusion barrier.

13. The method of claim 12, wherein the crystalline tungsten nitride-based layer includes nitrogen content of at least more than approximately 40%.

14. The method of claim 12, wherein the crystalline tungsten nitride-based layer is a polycrystalline thin film with regional crystalloids.

15. The method of claim 12, wherein the crystalline tungsten nitride-based layer is formed in a thickness ranging from approximately 30 Å to approximately 100 Å.

16. The method of claim 12, wherein the tungsten layer is formed in a thickness ranging from approximately 10 Å to approximately 60 Å.

17. The method of claim 11, wherein the silicon electrode includes one of polysilicon, polysilicon germanium (poly-Si₁₋ₓGeₓ), where x representing an atomic ratio of Ge ranges from approximately 0.01 to approximately 1.0, and metal silicide selected from a group consisting of Ni, Cr, Co, Ti, W, Ta, and Hf.

18. The method of claim 11, wherein the metal electrode includes a tungsten layer.

19. The method of claim 11, wherein the selective gate re-oxidation process is performed in one gaseous atmosphere of H₂O/H₂ and O₂/H₂.

20. The method of claim 19, wherein the selective gate re-oxidation process is performed at a temperature ranging from approximately 400° C. to approximately 850° C.

21. The method of claim 19, wherein the selective gate re-oxidation process is employing one of an annealing method and a plasma method.

22. The method of claim 11, wherein a silicide thin film is additionally inserted between the double diffusion barrier and the silicon electrode.

23. The method of claim 22, wherein the silicide thin film is selected from a group consisting of WSiₓ, TiSiₓ, TaSiₓ, MoSiₓ and HfSiₓ, and the constant x representing an atomic ratio of Si ranges from approximately 1.0 to approximately 5.0.
